(19) United States
(12) Patent Application Publication
(10) Pub. No.: US 2007/0061674 A1
(43) Pub. Date: Mar. 15, 2007

(54) Transmission data packet construction for better header authentication

(75) Inventors: Per Hvid Hansen, Lynge (DK); Per Einar, Pontus Holm, Tygelsjo (SE)

Correspondence Address: NOVO NORDISK, INC.;PATENT DEPARTMENT, 100 COLLEGE ROAD WEST, PRINCETON, NJ, 08540, US

(73) Assignee: Novo Nordisk A/S, Bagsvaerd (DK)

(21) Appl. No.: 11/513,085

(22) Filed: Aug. 30, 2006

Related U.S. Application Data
(63) Continuation of application No. PCT/DK05/00024, filed on Jan. 17, 2005.

(30) Foreign Application Priority Data
Mar. 2, 2004 (DK) PA 2004 00356

(51) Int. Cl. H03M 13/00

(52) U.S. Cl. 714/758

(57) ABSTRACT

The invention relates to a packet format for data being transmitted in a packet switched network. The packet as constructed in accordance with the invention enables the detection of data tampering and alteration of the data payload part as well as header part. The invention uses check code and encryption for constructing a secure packet but does not encrypt the header part of the transmission data packet.

The present invention relates to the field of packet-switched data communication devices. More specifically the invention relates to the construction and format of packets used during the transmission of data between two or more devices.

With the rapid growth of telecommunication industry and the web of network/s becoming more complex, serious concerns naturally are raised about security of data being transmitted over these networks.

Along with the increase in the type and number of devices (like Personal Computers, Cell phones, Personal Digital Assistants etc.) and their connectivity becoming an important feature, there has also been a marked increase in the amount of data being transmitted amongst them. Such data sometimes is private and/or sensitive in nature and therefore needs to be protected.

The data transmission over the digital network occurs in the form of strings of zeroes and ones (i.e. the bits of binary language). These bits often are grouped together as bytes.

For any two parties to effectively communicate (including humans, computers etc.) they have to follow a certain agreed protocol standard. This protocol identifies a set of rules and guidelines using which the parties communicate with each other. In the field of computer and telecommunication, the interaction between two entities occurs at various levels of abstraction and varied functionality. These levels are called the layers of the networking protocol and the combined set of protocol between each pair of communicating layers is called a protocol stack. As an example, one popular protocol stack is Open Systems Interconnection (OSI) Reference Model, the details of which are incorporated herein as reference. Various protocol layers also define the format in which the data has to be sent and received between them. The format of data typically is decided keeping various factors in mind, such as the functionality of the layer, security concerns, reliability factors, etc.

Networks can be classified by the manner in which data is transmitted. Two popular classifications are circuit switched and packet switched network. Switched networks involve a partially or fully meshed topology (i.e. partial or total connection between the nodes of the network) and use special network devices called switches to interconnect the links between source and destination nodes.

In a circuit switched network, a physical circuit first is established between the source and the destination before any transmission can take place. Once established, the physical circuit is dedicated exclusively to the current transmission. When the transmission completes, this circuit is then released and made available for another communication transmission.

In a packet switched network, messages first are partitioned into smaller units called packets, which are then sent to the destination nodes via intermediate switches. A packet is the smallest unit of data that can be transferred within a given network. Each packet header may carry destination node address, source address as well as other important information like protocol specific information, sequence number, length of data bytes, etc. When a packet arrives at an intermediate switch, the switch examines the packets destination address to determine which path the packet should take to the next switch. Once packets reach their destination, they cease to exist. Each packet, although varying in size, carries a small bit of data to and from one host to another. Each packet may also carry its own individual information. Different types of protocols construct different types of packets and they are accordingly read at the receiving end.

During transmission these packets are susceptible to various types of network errors and security threats, e.g. somebody tries to steal, copy or manipulate the data. Because of network errors etc, the data being transmitted at one end sometimes gets corrupt on the way in the path and the recipient consequently receives erroneous data. To avoid and address this problem, error checking and error correcting codes are used.

One of the methods widely accepted in the industry is to include a check code with the data packet. An error check code is a summary, or digest, of the data computed with some algorithm that can be checked at the receiving end.

Polynomial codes form one class of check codes. They are also known as Cyclic Redundancy Code or CRC code. Cyclic redundancy checking is a method of checking for errors in data that has been transmitted on a communications link. A sending device applies a 16- or 32-bit polynomial to a block of data that is to be transmitted and appends the resulting cyclic redundancy code (CRC) to the block. The receiving end applies the same polynomial to the data and compares its result with the result appended by the sender. If the result is agreed on between the parties, the data can be said to have been received successfully. Conversely, the sender can be notified to resend the block of data.

Polynomials such as CRC-12, CRC-16, and CRC-CCITT are widely used in the industry. CRC-12 is used when the character length is 6 bits. The other two are used for 8-bit characters. 16-bit cyclic redundancy code detects all single and double-bit errors and ensures detection of 99.998% of all possible errors. This level of detection assurance is considered sufficient for data transmission blocks of 4 kilobytes or less. For larger transmissions, a 32-bit CRC is used.

Commonly used “check code” or message digest algorithms used when authenticating messages are for example the MD5 algorithm (Internet Engineering Task Force RFC1321) or SHS (http://csrc.nist.gov/publications/fips/fips180-1/fip180-1.txt). These are considered more secure (i.e. tamper proof) as compared to a simple CRC check, but are also much more computational intensive and space consuming.

The bits and bytes in a packet (i.e. the basic unit of the digital transmission) are partitioned as a header part and a data part. After the introduction of the check code the packet broadly includes three parts i.e. the header part, the data part and the check code part. The introduction of check code in the packet takes care of the integrity of data being delivered.

The packets are also vulnerable to network threat in the form that they can be intercepted during transmission and their contents can be read, copied, modified or deleted or the header can be so modified so as to redirect them (to an unintended receiver) or as to provide erroneous information to the receiver. This sort of security breach raises doubts about the authenticity of the data that is being transmitted. Data modification can be detected by using error detection codes similar to the ones described above. To get around the problem of tampering with the packets, various means are adopted at one or more levels of protocol stacks.

One of the methods adopted to increase the security of the data being transmitted over a network is to encrypt the whole packet and then transmit it and thereafter decrypting it at the receiving end, thus making the header more secure and tamperproof to a certain degree. However, this approach has its drawbacks. Since in a packet switched network, a packet has to hop through several switches and routers, etc. in its journey from its source to its final destination, encrypting the header incurs an overhead. This overhead is incurred in terms of time and efficiency because at each intermediate routing element, the header has to be decrypted in order to know its contents so that it can be directed towards its (next) destination and then once again has to be encrypted, etc. This encryption-decryption-encryption step results in a substantial increase in the time taken to transmit a packet to its destination. Such overheads can also be expressed in terms of cost, as the switching elements have to be made smart, i.e. requiring sufficient computational power, enough so as to enable a fast encryption and decryption of the headers. Since secure cryptography is relatively time consuming, it is not suitable for time critical parts of the protocol stack. For this reason only the payload part of the packet are normally encrypted.

The above method does not help in a scenario wherein the packet is intercepted and the contents of its header are changed. Since the header is an important part of the packet (determining its destination, source and other important information), it is equally important to protect its data content as well. It therefore becomes imperative that any tampering to the header part of a packet can be detected at the receiving end.

Various steps have been taken in order to secure the data packets traveling over a network. However, most of them like U.S. Publication No. 2003/0065917 A1, and WIPO Publication No. WO03061289 A1 each relates to a scenario, wherein a point-to-point connection is established and data is then transmitted in a secure manner.

Attempts have also been made to secure the data that is being transmitted over a public network. For example in WO 03063520, the data is encoded in a symbolic form that is known only to the sender and the recipient thereby making it difficult to understand for the interceptors. However the header is not coded and can be tampered with.

WO 03050965 encrypts the data payload part of the packet using spread spectrum technique, providing a stronger security but the problem associated with leaving the header unprotected is still not addressed. WO 03005635 and U.S. Pat. No. 5,898,784 are few of the other patents that relate to various attempts made at secure transmission of data packets. But once again only data payload is secured, leaving the rest of the packet open to network threats.

U.S. Pat. No. 4,910,777 discloses encryption of the flag value of the packet and then transmitting it. However this methodology requires intelligent switching elements and also increases the computation being done at each switching of the packet.

U.S. Pat. No. 5,303,303 attempts to get around all the aforementioned drawbacks by introducing the concept of dummy headers and trailers. According to this invention the whole packet is encrypted and then a further header and trailer are provided to this encrypted packet. This further header and trailer contain information only about the entry and the exit nodes at which the further data packet enters and leaves the non-secure network. Therefore, any interception in between nodes will only provide information about the packet's path in the non-secure network and not about its original sender and recipient. This method would therefore fail in a scenario such as the Internet since such a network can be classified as being non-secure.

The drawbacks of the prior art have necessitated the introduction of such a methodology that is less computational resource hungry, is more time effective as well as being more secure and more robust.

It is an object of this invention to overcome the drawbacks of the prior art by providing a packet format and a method that not only protect the data payload of the packet but which also seal the header against any network attacks.

It is a further object of the invention to secure a full packet (i.e. its header as well as data payload) without requiring enhanced computational resources at each and every switching element.

It is also an object of the present invention to provide a security mechanism that is less time consuming and can be implemented using the existent resources present at the sending and the receiving end.

It is yet another object of the invention to have such a mechanism wherein the headers are not encrypted (for easier and faster transmission) but which at the same time makes it possible that any tampering with headers can be detected.

To overcome the drawbacks of the prior art and to achieve the aforementioned objectives, the present invention provides for a packet format which comprises of at least three parts viz. header part, data payload part and a check code part (e.g. using Cyclic Redundancy Code). According to the present invention, the check code is calculated for the combined header and the data payload part. Thereafter the data payload part and the check code part are transmitted in an encrypted form, but the header is transmitted as such. Any tampering with the header can easily be detected at the receiving end, e.g. by the discovery of a disparity using the check code part.

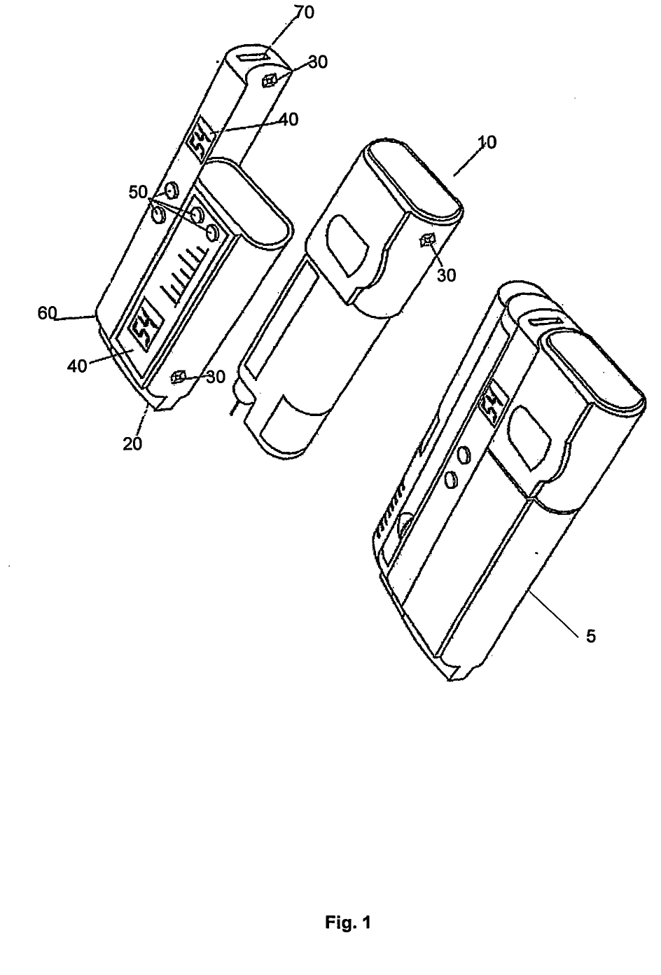

FIG. 1 shows a medical device in the context of which this invention is explained.

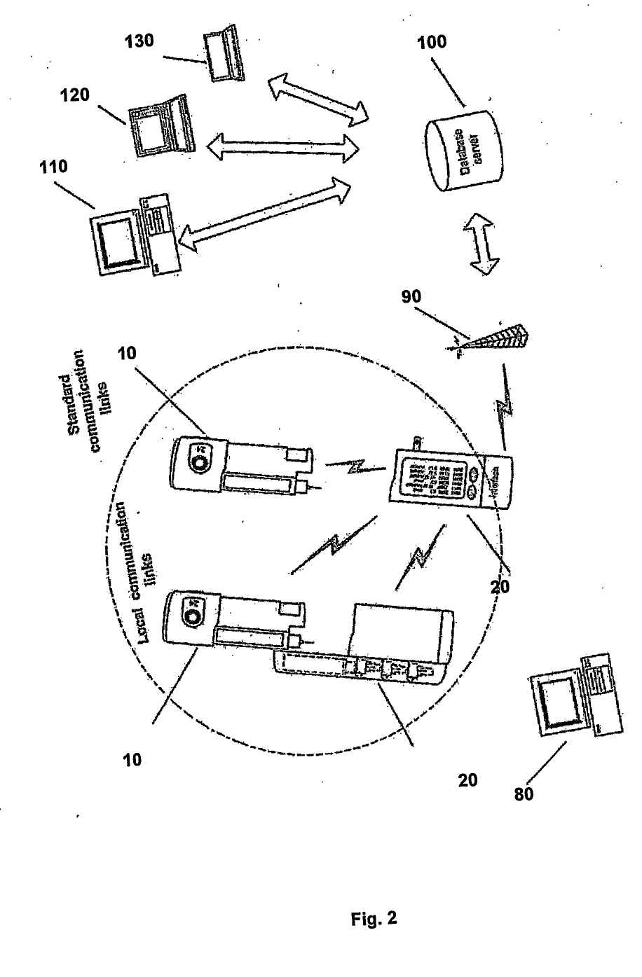

FIG. 2 exhibits the network scenario according to the one of the embodiments of the invention.

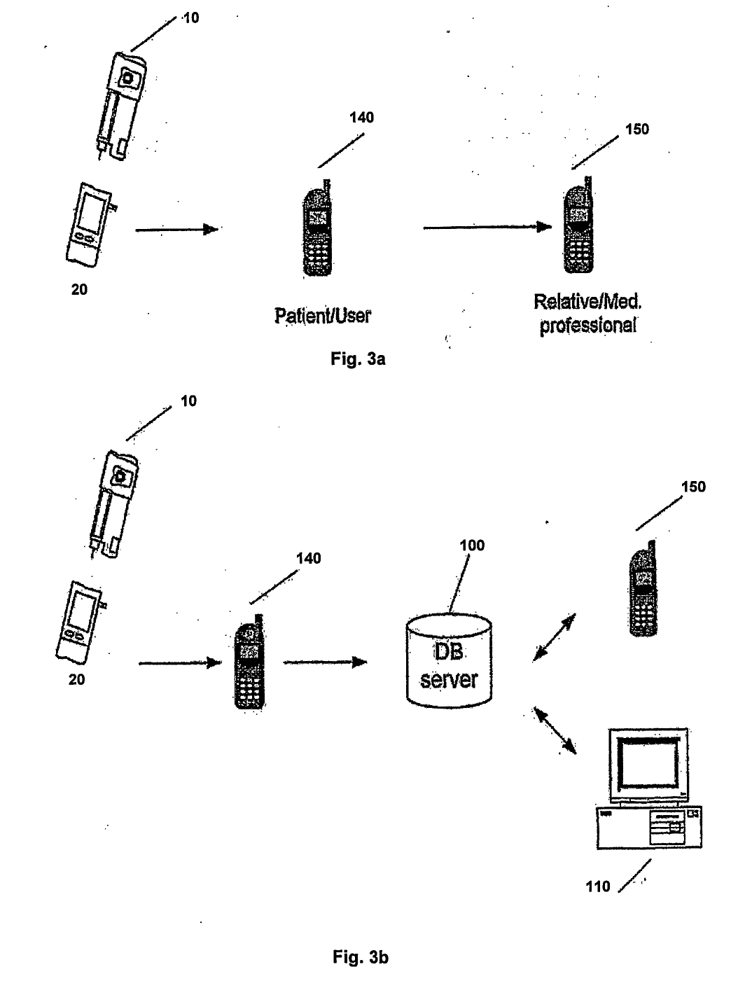

FIGS. 3a and 3b illustrate another set-up under which the invention might be practiced.

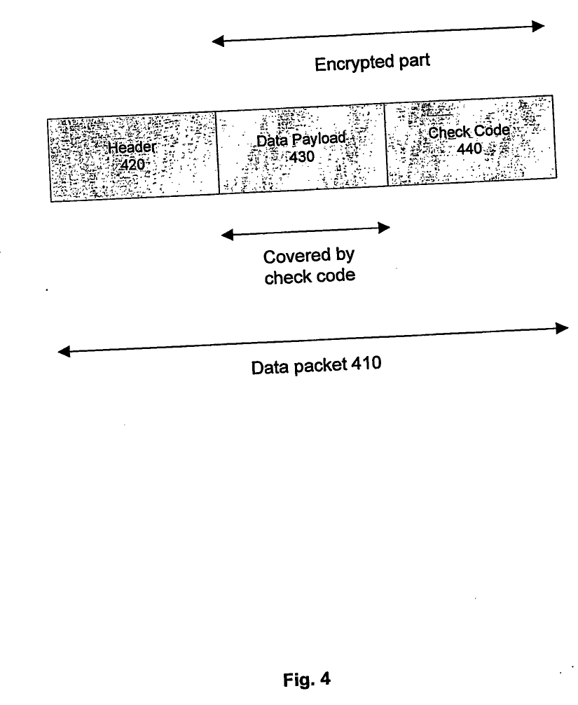

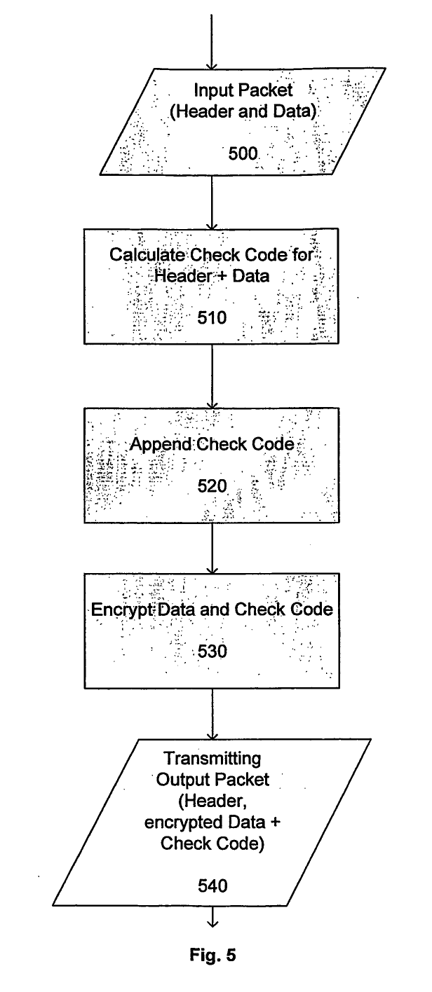

FIG. 4 shows the structure of the packet transmitted as known in the prior art. FIG. 5 is a flowchart of the method followed at the transmitting end according to the present invention.

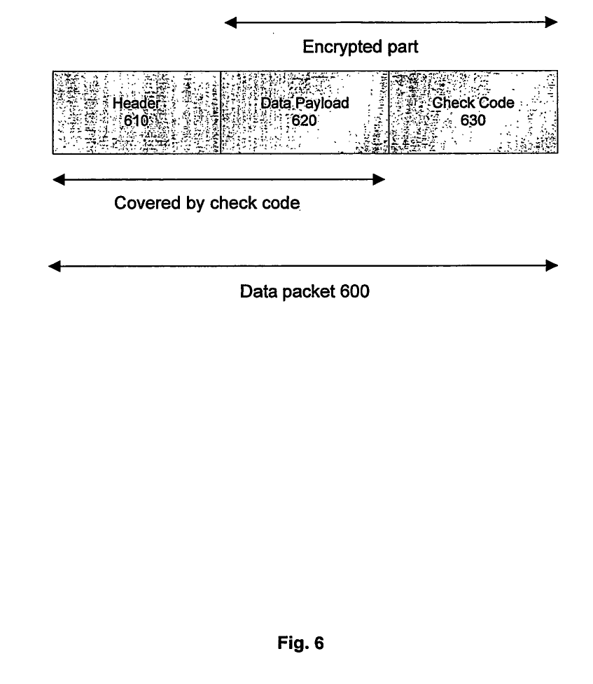

FIG. 6 shows the structure of the packet in accordance with the present invention.

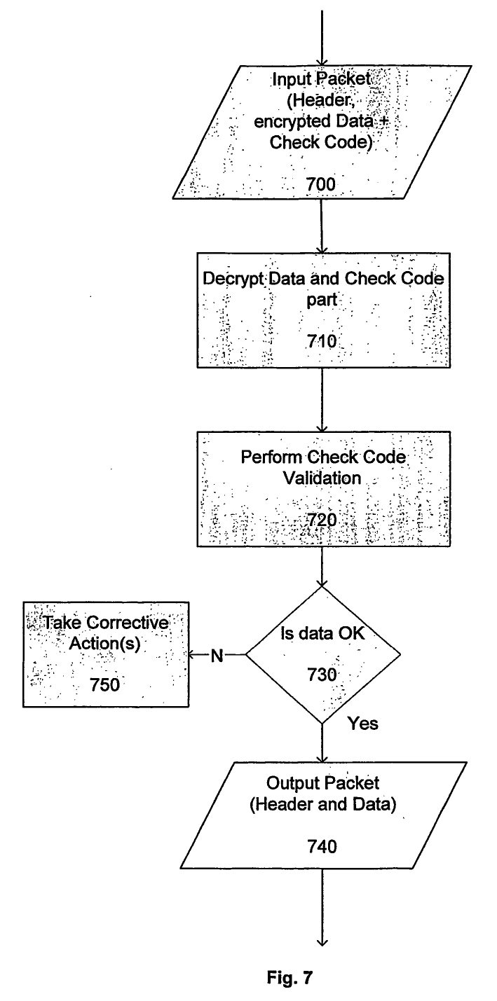

FIG. 7 is a flowchart for the method practiced at the receiving end implementing the invention.

The present invention provides a security mechanism for the packets being transmitted over any general network, protecting the packets against any alteration of data payload as well as sealing the headers so as to detect any tampering that might have happened to them on the traveled route.

The present invention can be carried out in any packet switched network. It can be a wired network like the Internet or wireless network like, such as wireless Ethernet, etc. the network can be secure, insecure, private, public or a any combination of the afore mentioned. Obviously the invention provides the most advantages in an insecure network. The generic packet format described herein can be implemented over any protocol like File Transfer Protocol (FTP), Transmission Control Protocol (TCP), Bluetooth, etc. The network topologies, such as a bus, star, ring etc., duplex, simplex etc will not be limit the application of the present invention. The method is equally applicable to computer networks as well as telecommunication networks and well as any other network wherein digital data is to be transmitted in a secure way according to the present invention.

There are numerous applications of the present invention and the explanation of FIGS. 1, 2 and 3 are just meant as an illustration and are in no cases meant to be limiting. For instance the present invention is equally effectively applicable for secure transaction over the Internet as well as a medical device network, in the contexts of which the application of the invention now will be explained.

The advancement in the field of medicine has increased the lifespan of humans significantly by having better treatment for acute diseases and enhanced medication and therapy for chronic diseases. This benefit of a longer life is sometimes overshadowed by frequent trips to the doctor for administration of drugs and medication. These trips are neither time nor cost effective. Therefore a need arises for self-care/treatment and medication, where frequent trips to health care personal are minimized. Technology thus comes out with a solution by the introduction of drug-administration devices that can be easily operated by a person of average level of intelligence and education. These devices, typically, are easy to use and rather fool safe. For example devices to inject insulin (for diabetes patients), inhalers (for asthma patients), blood sample collection device etc are widely available in the market.

However some patients especially those of an older age require constant reassurance that each and every step are being performed in a right manner, i.e. the device is working reliably and that the right amount of drug as intended is being administered. Further some patients might require to be reminded of the date and time of their drug-administration therapy. It is also desirable to have some sort of report being sent to the patient's doctor and/or somebody near and to some dear ones. This report is not only a help for the doctor when checking the patient's progress and present condition, but it also helps him to decide upon a future scheme of medication. This report can also act as a logbook of patient's activity and his habits over a period of time. Sometimes this data can also be required by a health care-team to take necessary corrective steps in an emergency situation. Ideally all these data-collection and transmission activities should therefore be performed with as little involvement for the patient (or people around him) and should also be unobtrusive in his day-to-day life. The solution came with the introduction of smart drug-administration devices that are capable of having wireless communication with other computing devices, together forming a patient-doctor-relative network that works towards keeping a better care of the patient.

International Publication No WO 00/32088, WO 03/005891 and WO 03/015838 all describe such medical devices, networks and method of their operation along with some of the possibilities in the domain. In the following, such devices and networks are discussed on which the invention can be implemented.

In the present context, the term ‘medical device’ can mean an injector type device (such as a pen injector or a jet injector) for delivering a discrete dose of a liquid medication (possibly in the form of small drops), a medication pump for continuous delivery of a liquid medication, an inhaler, spray or the like for delivering a discrete or continuous dose of a medication in vaporized, ‘atomized’ or pulverized form, preferably the medication is insulin. The medical device can also mean a blood glucose tester or a BGM (blood glucose measurement device), e.g. a device using so-called test-strips for the manual measurement of the glucose level in the blood or a more advanced device, i.e. a CGM (continuous glucose measurement device) performing automatic continuous measurements of the blood glucose level.

U.S. Pat. No. 6,540,672, U.S. Pat. No. 6,656,114, U.S. Ser. No. 2002010432 and U.S. Ser. No. 2003032868 all disclose intelligent medical devices, which are hereby incorporated by reference in its entirety. U.S. Pat. No. 5,888,477 (which is hereby incorporated by reference in its entirety) discloses an inhaler with robust features that may be used for insulin delivery. U.S. Pat. No. 5,785,049 to Smith et al (which is hereby incorporated by reference in its entirety) discloses a device suitable for powdered medication delivery.

FIG. 1 is an illustration of one of the smart devices 5 that is a combined instrument capable of administering insulin to a diabetes patient as well as analyzing blood sugar levels, as disclosed in International Publication No WO 00/32088, which is incorporated herein as a reference. This device has a doser module 10 and a functional master module 20. Data transmission and receiving means 30 are provided to enable data communication. The user can also store the data and view it at a later stage using the display provided. One or more buttons 50 may be provided to enable the user to control the unit and to have a better user interaction with it.

FIG. 2 shows one of the possibilities of the patient-doctor-relative network. The patients have aforementioned intelligent devices, such as two doser modules 10 also as explained in FIG. 1 with said functional module caps. These dosers communicate with various computing means using various networks and protocols. The network possibilities include Personal Area Network, Internet, Local Area Network, etc. Additionally communication can also be done between a device and the patient's computer 80. In some embodiments the data might also be transmitted and stored in a central database server 100, using various communication links such as Local Area Network, RS-232 links, satellite communications etc. Further the device can also communicate the stored data through various communication means 90 such as a telephone link to a central database 100. The centralized database can also be accessed using various computing devices 110, 120, 130 connected over a network. This database can also be used to transmit information to the device 5 as shown in the aforementioned figure. This network is explained in further detail in International Publication No WO 03/005891, which is enclosed herewith as a reference.

FIG. 3a and 3b each shows an advanced network in which telecommunication devices interface with the computer network providing greater flexibility in operation. In FIG. 3a the doser 10 and functional master module cap 20 communicate to a relevant third party's (i.e. a doctor, relative, health care-team, etc.) mobile communication terminal 150 through a mobile communication terminal/wireless access point 140. The communication can be any protocols depending upon the requirement, as an example Bluetooth might be used for device-mobile communication and GSM may be used for mobile-mobile communication or vice versa. The information can be exchanges of data using applications such as SMS (Short Messaging Service), MMS or e-mail. The display in the device can be further enhanced to include these capabilities.

FIG. 3b shows a slightly different scenario, in a case where a connection has been established between the device 10 and the user's mobile terminal 140 (as explained above), the information received is transmitted to a database server 100 using protocols such as GPRS, TCP/IP (Transmission Control Protocol/Internet Protocol), GSM, etc. The stored information can then be accesses by relevant third parties using a mobile terminal (e.g. using Wireless Access Protocol) 150 or a computer 110 over any known network links. Alternatively, a server may also transmit the information as SMS and/or email. The above networks are described in greater detail in International Publication No. WO 03/015838, incorporated herein as a reference.

The scenarios as mentioned above have the underlying requirement that the data being transmitted is secure from eavesdropping, tampering and any other harmful activity, which, if taken place, not only is a personal infringement of data but may also be sensitive and critical to life, if wrong data is misinterpreted. Although various methods such as encryption, etc. can be used while transmitting the packets but the problem of the header being open to tampering, etc still remains. The present invention intends to address this problem and the solution disclosed herein applies not only to the networks of the kind as described above, but also to packet switched networks.

FIG. 4 shows a general packet structure. The data packet 410 comprises three distinct parts, i.e. a header 420, data payload 430 and a check code 440. This check code can be chosen according to the requirements from the protocol and the format of the data to be transmitted. The most prominently used check code is Cyclic Redundancy Code or CRC code. It exists in various variants like CRC-12, CRC-CCITT etc. Check code is a polynomial based technique that is used to check for the validity of data being transmitted. The method and the technique adopted to insert and read a check code so as to validate the data are beyond the scope of this patent and are hence not being discussed here. Broadly speaking the check code methodology follows these steps:
Step 1: At the transmitting end, a check code is calculated for the data payload using a known generator polynomial G(x) and is appended to the packet. This check code is generally appended at the end of the packet but other formats are also possible.
Step 2: The data packet is transmitted with a header (containing information about the destination amongst other things), data payload and a check code part.
Step 3: At the receiving end, the data and appended check code part are divided by the polyanomial G(x). If any remainder is obtained as a result of this division, there has been some error in the transmission and corrective steps are likely to be taken.

To provide security to the data being transmitted, sometimes the data and check code part are encrypted at the transmitter end and at the receiving end as well. The data and check code part are first decrypted and then the check code is verified. The encryption can be carried out using any commonly agreed algorithm and method.

As mentioned earlier the header part of the packet is not generally encrypted because of its time critical nature, and the packet is therefore open to network attacks. In such a situation it is near impossible to detect the tampering of header information and take any corrective actions.

The present invention describes a packet format that although does not have an encrypted header (therefore having the advantage of being less complicated and having a faster transmission) but has means to detect any tampering, that might have happened in the header or the data payload during transmission. This packet is formed by following the method as described by the flowchart of FIG. 5.

The raw packet, i.e. just the header and the data payload is taken as an input 500. Check code is calculated for the combined header and the data part 510 and thereafter appended to the original data packet 520. The next step encrypts the data part and the check code part 530. As pointed out above, the use of encryption algorithm is purely a subject matter of choice and agreement between the transmitting and the receiving ends. This invention is not effected by the preference of one encryption algorithm over another. It is possible to apply symmetric, asymmetric algorithms like DES, RSA, SHA, etc. Needless to say, the stronger the algorithm, the more secure the data transmission will be as a result. The resulting output 540 of the method is a packet, which is shown in detail in FIG. 6.

The packet format—shown in FIGS. 4 and 6—shows the check code part located at the end portion of the data packet, it is meant to be just an example and is not limited in any respect. The present invention applies wherever the check code is located within the packet.

FIG. 7 shows the process followed at the receiving end to check for any tampering of the data packet during the transmission stage. The packet as shown in FIG. 6 acts as an input for the receiving end. Firstly, the data and the check code part are decrypted 710. As a next step, Check Code validation is carried out 720. If this is comes out to be OK 730, the packet is outputted 740 without the check code and the data payload is used. Alternative, i.e. if the Check Code validation carried out turn out to be not OK, corrective action(s), such as request for retransmission, etc is/are (to be) taken 750 as a consequence.

If any tampering is done with the data payload or the header part, the CRC check will fail, thus it is then possible to inform the recipient of some error and/or foul play with his intended data. The header is free from any encoding or encryption during transmission therefore no computational intensive tasks have to be done at the switching elements saving time as well as resources.

The aforementioned method can be implemented using a set of instructions being run on a computing device in the form of hardware or software or by means of a combination of both. The present invention is independent of the language and the codification used in the implementation of the above method at various levels of abstraction. The computing device can be any general computing device having processing means, control unit, storage means and internal communication means, e.g. a medical device.

In the following a working example of the invention is discussed:

Generic Data Format

A packet is typically divided into header, data, and checksum parts. The header contains destination address, destination channel, message type and a packet sequence number. The data part includes length a command identifier and parameters.

| | | Field | | Size | |
|---|---|---|---|---|---|
| Byte | Part | name | Type | (bytes) | Description |
| 0 | HEADER | desti- | Addr_t | 4 | Destination |
| | | nation | | | address of packet. |
| | | | | | The destination |
| | | | | | consists of a |
| | | | | | unique device |
| | | | | | identifier and a |
| | | | | | channel number. |
| | | | | | Address 0 is |
| | | | | | reserved for |
| | | | | | broadcast messages. |
| 4 | | chan | Channnel_t | 1 | Channel number |
| 5 | | type | eMsgType | 1 | Type of packet |
| 6 | | seq | uint8_t | 1 | Frame number |
| 7 | | len | uint8_t | 1 | Length of data |
| 8 | DATA | cmd | eCmd | 2 | Command identifier |
| 10 | | status | eStatus | 1 | Error status code |
| 11 | | param | | 0-255 | Parameters as |
| | | | | | described for |
| | | | | | specific commands. |
| n-3 | CHECK | crc | Crc_t | 2 | Cyclic Redundancy |
| | | | | | Checksum |
| | | | | | (CCITT CRC16) |
| | | | | | of all previous |
| | | | | | fields. |

Header Part

The header part contains address and other information needed by the protocol to deliver the data part. The header is typically never encrypted but it is included in the checksum calculation.

Destination

The destination is the destination address of a packet. A device address is a unique device identifier for each device. Address 0 (addrBroadcast) is reserved for broadcast messages.

Channel

The chan parameter specifies channel number in the destination device. Channel 0 (chnAny) may be reserved for assignment messages.

Type

The message type field indicates the general type of the message.

eMsgType

| Value | Enumerator | Description |
|---|---|---|
| 0 | mtReq | Request from client to server |
| 1 | mtReply | Response from server to client |
| 2 | mtAck | Reply acknowledge from client to server |
| 3 | mtSimple | Unsolicited message from server to client |
| | | (no handshake provided) |
| 4 | mtSimpleReply | Reply on a Unsolicited message |
| | | (No handshake provided) |

Sequence

The sequence number is used to remove duplicates of sent messages. The number may be increased for each packet of type mtReq and mtReply. The sequence numbers wraps around to one (not zero) after 255. The sequence number 0 is used to re-synchronize a channel, for example when a device is powered up and has lost it's state. When a packet with sequence number zero is received the cryptography state should be flushed.

Length

Length of the data part in bytes. Maximum length is the negotiated maximum packet size minus size of header and check parts, that is, e.g. MaxBufferSize—10. Minimum length is 3 (size of cmd and status fields). Length 0 may be used in the Acknowledge message as special case.

Data part

If the data part is not empty it always begins with a command identifier.

Cmd

Identifies the command. 0-15 may be reserved for protocol messages. 16-255 may be used for common commands. The range 256-65535 may be used for device specific commands; each device type receives a range of 256 identifiers.

Status

The Status field contains an error code for command response packets. If the status code indicates an error then the param field may be omitted.

eMsgStatus

| Value | Enumerator | Description |
|---|---|---|
| 0 | errOK | Command completed successfully |
| 1 | errCmdNotImpl | The command is not implemented on |
| | | this device. The param field is empty. |
| 2 | errFailed | Command failed |

Param

The variable size data part contains parameters or data specific for each command.

Check Part

All fields including destination are used when calculating the crc. If encryption is used then the Data and Check parts are encrypted but not the header. By including the crc field in the encrypted data an automatic authentication of the header is achieved (using the crc as the hash or message digest). Note that the crc is calculated on unencrypted data.

1. A transmission packet format 600 for use in a communications network, said packet format comprising:
a header part 610,
a data payload part 620, and
a check code part 630, characterised in that, the check code is for the combined header and data payload part; and the data payload part and check code part are in an encrypted format.

2. The transmission packet format 600 of claim 1, wherein the check code includes Cyclic Redundancy Check (CRC) Code.

3. The transmission packet format of claim 1, wherein the encryption is carried out using any known encryption algorithm including symmetric and asymmetric key algorithms.

4. A communication protocol for a computer network comprising packets configured to authenticate the contents of the packet including the header part and the data payload part.

5. The communication protocol of claim 4, wherein packet authentication is achieved by calculating a check code of the packet header and data payload; and encoding data payload and the check code.

6. A method for transmitting data packets in a communication network with full packet authentication facility, each said packet comprising of a header part, data payload part and a check code part, said method comprising the steps of:
calculating the check code for the header part and the data payload part 510,
appending the check code with the data packet 520,
encrypting the data payload part and the check code part 530, and
transmitting the encrypted packet 540.

7. The method of claim 6, wherein the check code includes Cyclic Redundancy Check (CRC) Code.

8. The method of claim 6, wherein the encryption is carried out using any known encryption algorithm including symmetric and asymmetric key algorithms.

9. A computer program product comprising computer readable program code stored on a computer readable storage medium embodied therein for transmitting data packets in a communication network with packet authentication facility, each said packet comprising of a header part, data payload part and a check sum part, comprising:
computer readable program code means configured for calculating the check code for the header part and the data payload part,
computer readable program code means configured for appending the check code with the data packet,
computer readable program code means configured for encrypting the data payload part and the check code part, and
computer readable program code means configured for transmitting the encrypted packet.

10. A method for reading data packets received constructed in accordance with the format or method as described in any of the aforementioned claims, said method comprising the steps of:
decrypting the data and the check code part 710,
validating the check code 720,
taking corrective actions in case where the check code validation failed 750, and
using the data payload in the case of a validated check code 740.

11. A computer program product comprising computer readable program code stored on a computer readable storage medium embodied therein for checking of tampering of data packets received in accordance with the format or method as described in any of the aforementioned claims, comprising:
computer readable program code means configured for decrypting the data and the check code part,
computer readable program code means configured for validating the check code,
computer readable program code means configured for taking corrective actions in case where the check code validation failed, and
computer readable program code means configured for using the data payload in the case of a validated check code.

12. A system for transmitting and reading data packets in a communication network with header authentication facility, each said packet comprising of a header part, data payload part and a check sum part, comprising:
means to construct the packet using the method as claimed in claim 6,
means to transmit the packet, and
means to read the packet using the method as claimed in claim 10.

13. The system of claim 12, wherein the said means wholly or partially reside on a computing system comprising:
at least one system bus,
at least one communications unit connected to the system bus,
at least one memory unit including a set of instructions, said unit connected to the system bus, and
at least one control unit executing the instructions in the memory for the functioning of said means.
